(19) United States
(12) Patent Application Publication
(10) Pub. No.: US 2015/0179451 A1
(43) Pub. Date: Jun. 25, 2015

(54) METHOD FOR PROCESSING GRAPHENE, METHOD FOR PRODUCING GRAPHENE NANORIBBONS, AND GRAPHENE NANORIBBONS

(71) Applicant: TOKYO ELECTRON LIMITED, Tokyo (JP)

(72) Inventor: Takashi Matsumoto, Tsukuba-shi (JP)

(73) Assignee: TOKYO ELECTRON LIMITED, Tokyo (JP)

(21) Appl. No.: 14/390,402

(22) PCT Filed: Mar. 27, 2013
(86) PCT No.: PCT/JP2013/058909

§ 371 Date: Oct. 3, 2014

(30) Foreign Application Priority Data
Apr. 5, 2012 (JP) 2012-086173

(51) Int. Cl. H01L 21/04

(52) U.S. Cl. CPC H01L 21/042

(57) ABSTRACT

A gas comprising H₂O molecules is introduced into a cluster-generating unit through a nozzle of a gas cluster ion beam device. The introduced water vapor is aggregated by cooling by adiabatic expansion, and beam-shaped H₂O clusters are formed. The H₂O clusters, having been introduced into an irradiation unit, are ionized by an ionization device. The H₂O clusters, having been ionized and positively charged, are drawn out by a plurality of electrodes to which a lower voltage than that of the ionization device is applied; after acceleration, focusing of the beams, and separation of cluster sizes by the electrodes, a substrate on which a sheet of graphene has been formed is irradiated to etch the graphene into nanoribbons having edges of an armchair shape.

### TECHNICAL FIELD

The present disclosure relates to a method for processing graphene useful as materials for various electronic components, a method for producing graphene nanoribbons, and nanoribbons obtained by the same method.

### BACKGROUND

Graphene has a structure in which carbon atoms are regularly arranged in a hexagon pattern on a plane and also has very high electrical conductivity. The graphene has attracted attention as the next generation high-frequency device material because of its excellent physical properties such as electron mobility of 200,000 cm²/Vs which is 100 times or more as large as that of silicon (see, e.g., Patent Document 1: Japanese laid-open publication No. 2008-205272, Patent Document 2: Japanese laid-open publication No. 2011-114299 and Patent Document 3: Japanese Patent No. 4669957). In addition, since the graphene can transport electrons as well as spins ballisitically, it is expected that it can be applied to spinstronic devices. The graphene having such characteristics is a zero gap semiconductor and cannot be in an OFF state in its current status. However, when the graphene has a nanoribbon structure whose line width is 100 nm or less, its band gap increases in inverse proportion to the line width. It is, however, known that the graphene has two types of edges, i.e., a zigzag edge (cis-polyacetylene-like structure) and an armchair edge (trans-polyacetylene-like structure). If a graphene nanoribbon does not have an armchair edge, the graphene nanoribbon produces no large band gap.

As a graphene patterning method, there has been proposed a method for forming a graphene structure patterned using chemical affinity on a substrate subjected to hydrophilic treatment and hydrophobic treatment (see, e.g., Patent Document 4: Japanese laid-open publication No. 2011-121828). Electron beam lithography is frequently used for the graphene patterning. However, this lithography method has a problem of damage to graphene of a channel part due to oxygen plasma etching and a problem of deterioration of transistor performance due to residue from the mask material. As a processing method other than the electron beam lithography, for example, there has been known an anodic oxidation method using a cantilever of an atomic force microscope (AFM) (see, e.g., Non-Patent Document 1: “NANOSCALE PATTERNING OF GRAPHENE USING AFM LOCAL ANODIC OXIDATION”, K. YOSHIDA, S. MASUBUCHI, M. ONO, K. HIRAKAWA, T. MACHIDA, Technical Digest. International Symposium on Graphene Devices: Technology, Physics, and Modeling, 2008). This method is capable of fine processing with precision of 10 nm or less which is substantially equal to the radius of curvature of the AFM cantilever but is, however, inappropriate for large area processing at a level of 300 mm wafer, which may result in a poor throughput.

There has also been proposed a method for etching graphene through the use of Ni catalysis nanoparticles (see, e.g., Non-Patent Document 2: “Evaluation and Processing of Graphene on Structure-Controlled Solid State Substrate”, Toshio Ogino and Takahiro Tsukamoto, Japanese Association of Crystal Growth, Journal 37(3), 207-213, 2010). However, in this method, it is difficult to place the Ni catalysis nanoparticles at any positions on the graphene surface, and thus it is difficult to perform a fine patterning with precision.

In any of the above-described conventional methods, it is difficult to produce the graphene edge such that the graphene edge is divided into the zigzag edge and the armchair edge.

### SUMMARY

The present disclosure provides a method for processing graphene, which is capable of etching graphene without damaging the graphene, a method for producing graphene nanoribbons, and graphene nanoribbons.

According to one embodiment of the present disclosure, there is provided a method for processing graphene, including: etching graphene by irradiating the graphene with an ion beam formed by ionizing water molecules or water molecule-agglomerated clusters by means of a gas cluster ion beam apparatus. In this case, in some embodiments, sheet-like graphene is processed into graphene nanoribbons whose edge is an armchair edge.

According to another embodiment of the present disclosure, there is provided a method for producing graphene nanoribbons, including: producing graphene nanoribbons whose edge is an armchair edge by irradiating sheet-like graphene with an ion beam formed by ionizing water molecules or water molecule-agglomerated clusters by means of a gas cluster ion beam apparatus.

According to another embodiment of the present disclosure, there is provided graphene nanoribbons whose edge is an armchair edge obtained by irradiating sheet-like graphene with an ion beam formed by ionizing water molecules or water molecule-agglomerated clusters.

According to the present disclosure, graphene nanoribbon can be processed without causing damage, by irradiating the graphene with water molecules or water molecule-agglomerated clusters by means of a gas cluster ion beam apparatus.

### BRIEF DESCRIPTION OF THE DRAWINGS

FIG. 1 is a schematic view of a gas cluster ion beam apparatus which can be used for a graphene processing method according to one embodiment of the present disclosure.

FIG. 2A is a view schematically illustrating sheet-like graphene to be processed according to one embodiment of the present disclosure.

FIG. 2B is a view schematically illustrating a state of graphene nanoribbons produced from the sheet-like graphene of FIG. 2A by etching.

### DETAILED DESCRIPTION

### <Gas Cluster Ion Beam Apparatus>

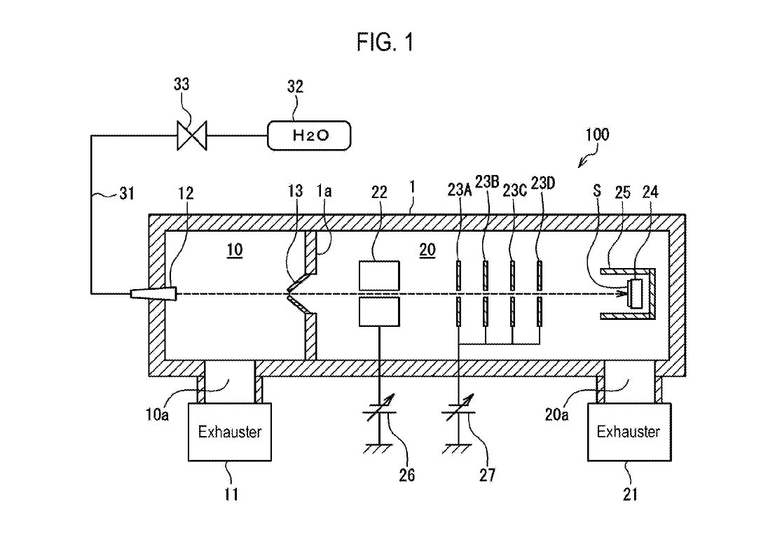

FIG. 1 is a schematic view of a gas cluster ion beam apparatus which is suitable to be used for a graphene processing method according to one embodiment of the present disclosure. The gas cluster ion beam apparatus 100 includes a vacuum container 1. The vacuum container 1 includes a cluster generating unit 10 and an irradiating unit 20 which are separated from each other by a partition wall 1a. The irradiating unit 20 is accommodated therein with a substrate S having a surface as a workpiece on which sheet-like graphene is formed.

The cluster generating unit 10 is connected to an exhauster 11 including a vacuum pump (not shown) and so on via an exhaust port 10a so that the interior of the cluster generating unit 10 can be exhausted. The cluster generating unit 10 is arranged therein with a nozzle 12 configured to introduce vapor (H₂O) as a gas for gas cluster generation. The partition wall 1a separating the cluster generating unit 10 from the irradiating unit 20 is formed with a skimmer 13 having a hole through which an H₂O cluster introduced from the nozzle 12 is passed. The skimmer 13 has the function of separating gaseous molecules which do not form cluster from a cluster beam. Although not shown, the nozzle 12 and the skimmer 13 are grounded at a potential of OV.

The irradiating unit 20 is connected to an exhauster 21 including a vacuum pump (not shown) and so on via an exhaust port 20a so that the interior of the irradiating unit 20 can be exhausted. The irradiating unit 20 is arranged therein with, in the order from the partition wall 1a, an ionizer 22 configured to ionize the gas cluster by colliding electrons with the gas cluster, a plurality of electrodes 23A, 23B, 23C and 23D configured to apply an electric field to gas cluster ions to accelerate the gas cluster ions toward the substrate S as the workpiece, and a Faraday cup 25 accommodated therein with a holder 24 which holds the substrate S. The ionizer 22 includes an electron source (not shown) configured to supply electrons to be collided with the gas cluster. The ionizer 22 is maintained at a positive potential by means of an ionizer power supply 26. The plurality of electrodes 23A to 23D interposed between the ionizer 22 and the substrate S held on the holder 24 are maintained at a negative potential by means of an electrode power supply 27. The number of electrodes arranged to apply an electric field to the gas cluster ions is not limited to 4.

The nozzle 12 is connected, via a high pressure gas supply pipe 31, to a H₂O source 32 configured to supply high-pressurized vapor. The high pressure gas supply pipe 31 is provided with a switching valve 33.

### <Etching Method>

In the gas cluster ion beam apparatus 100 as configured above, the interior of the cluster generating unit 10 is decompressed by differential exhaust using the exhauster 11 and the exhauster 21 of the irradiating unit 20. Next, a gas (vapor) containing H₂O molecules is introduced into the cluster generating unit 10 via the nozzle 12 installed within the cluster generating unit 10. The introduced vapor is agglomerated by cooling due to adiabatic expansion, thereby forming a beam-shaped H₂O cluster. The H₂O cluster thus formed is mainly introduced into the irradiating unit 20 since non-clustered H₂O molecules are separated by the skimmer 13.

The H₂O cluster introduced into the irradiating unit 20 is ionized by the ionizer 22. The ionizer 22 ionizes the cluster by drawing electrons out of the electron source (not shown) and colliding the electrons with the H₂O cluster.

As described above, the ionizer 22 is maintained at a positive potential by means of the ionizer power supply 26. The electrodes 23A to 23D are set to a potential lower than the potential of the ionizer 22 by means of the electrode power supply 27. Accordingly, the H₂O cluster ions ionized by collision with electrons and then positively charged are drawn by the plurality of electrodes 23A to 23D applied with a voltage lower than that of the ionizer 22. That is, in order to draw a H₂O cluster ion beam out of the ionizer 22 and transport it to the substrate S, a region formed between the ionizer 22 and the electrodes 23A to 23D is maintained at a potential difference of several tens of kV. The H₂O cluster ions drawn out of the ionizer 22 are accelerated by the electrodes 23A to 23D and are emitted onto the substrate S after being subjected to beam focusing and cluster size separation. Since the gas cluster ion beam apparatus 100 emits a great amount of H₂O cluster ions ionized as mentioned with a small current, it can achieve a high processing rate and provide less irradiation damage to a workpiece surface of the sheet-like graphene.

### <Processing Conditions>

In the method for processing graphene according to this embodiment, the gas cluster ion beam apparatus 100 shown in FIG. 1 is used to process the graphene. Conditions for the use of the gas cluster ion beam apparatus 100 as shown in FIG. 1 for processing the graphene may include a condition of being able to restrain kinetic energy per molecule at a low level, e.g., in some embodiment, being able to retrain kinetic energy per molecule at 10 eV or less.

In the gas cluster ion beam apparatus 100, H₂O molecules or H₂O molecule-agglomerated clusters are ionized, and then accelerated and transported as an ion beam. In some embodiments, the ion beam is controlled to have a kinetic energy per molecule of 10 eV or less and is irradiated to the graphene. The graphene is etched at an irradiated portion by the following chemical reaction of H₂O and the graphene.

C+2H₂O→CO₂+2H₂, or

C+2OH→CO₂+H₂

In the above reaction, by restraining the per-molecule kinetic energy of the ion beam to a low value, in some embodiments 10 eV or less, a chemically active zigzag edge of the graphene is preferentially reacted and then etched by H₂O. This results in graphene formed with a chemically stable armchair edge. In addition, when the graphene is processed to provide a nanoribbon shape having a width of 100 nm or less, a band gap can be formed from the graphene of a zero gap semiconductor.

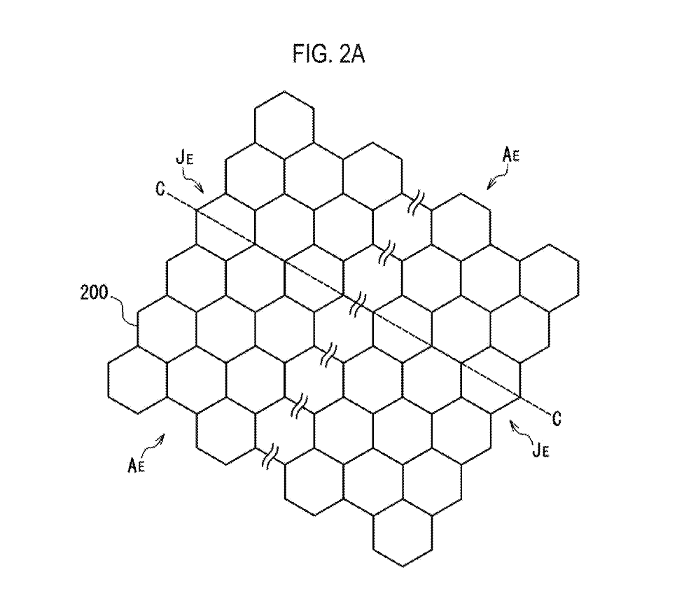

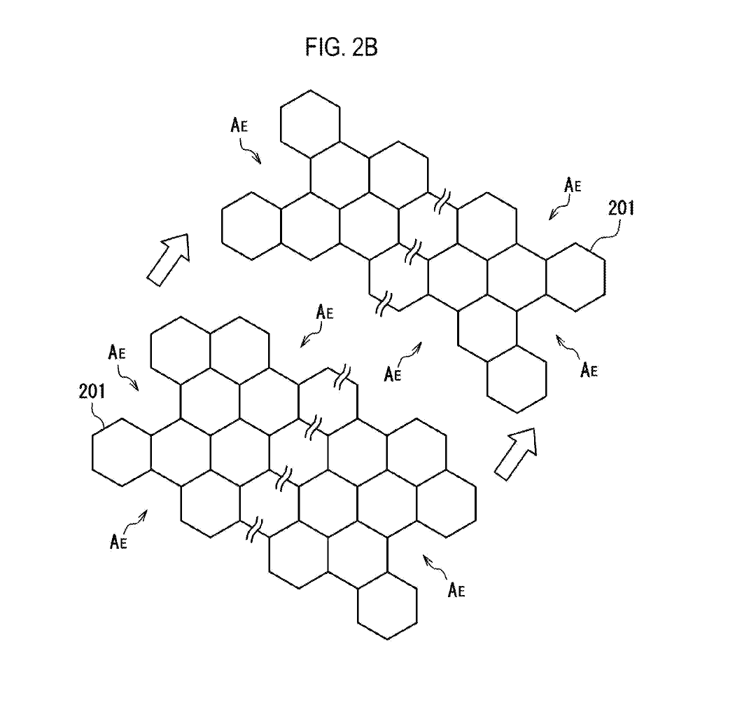

FIG. 2A is a view schematically illustrating sheet-like graphene 200 to be processed according to this embodiment. When the gas cluster ion beam apparatus 100 is used to irradiate the sheet-like graphene 200 of FIG. 2A with an ion beam, zigzag edges J_{E} are cleaved. In FIG. 2A, a cleaved portion is indicated by a dashed line C-C. Thus, graphene nanoribbons 201 of armchair edges A_{E} as shown in FIG. 2B can be produced.

As described above, in the graphene processing method of this embodiment, the H₂O cluster ions are specifically used to enable lower energy etching than using other gas species such as oxygen, ozone or the like. In addition, since H₂O has a weaker oxidizing power, the zigzag edges J_{E} can be selectively etched. In contrast, if the graphene is etched with oxygen or ozone having a stronger oxidizing power, the etching occurs randomly, which makes it difficult to selectively etch the armchair edges A_{E} and the zigzag edges J_{E}.

In this manner, the graphene processing method of this embodiment allows the zigzag edges J_{E} of the graphene to be selectively etched by the gas cluster ion beam apparatus, which irradiates the graphene with the ion beam formed by ionizing the water molecules or the water molecule-agglomerated clusters. In addition, the graphene processing method of this embodiment is capable of efficiently producing graphene nanoribbons having an armchair edge shape and a large band gap.

Although embodiments of the present disclosure has been described in detail for the purpose of illustration, the present disclosure is not limited the particular embodiments described. For example, although the processing of nanoribbons from the sheet-like graphene has been described in the above embodiment, the graphene processing method of the present disclosure may be used to reduce the number of layers of two or more-layered graphene by etching the graphene from the top layer.

This application claims the benefit of Japanese Patent Application No. 2012-086173, filed on Apr. 5, 2012, in the Japan Patent Office, the disclosure of which is incorporated herein in its entirety by reference.

What is claimed is:

1. A method for processing graphene, comprising:
etching graphene by irradiating the graphene with an ion beam formed by ionizing water molecules or water molecule-agglomerated clusters by means of a gas cluster ion beam apparatus.

2. The method of claim 1, wherein sheet-like graphene is processed into graphene nanoribbons whose edge is an armchair edge.

3. A method for producing graphene nanoribbons, comprising:
producing graphene nanoribbons whose edge is an armchair edge by irradiating sheet-like graphene with an ion beam formed by ionizing water molecules or water molecule-agglomerated clusters by means of a gas cluster ion beam apparatus.

4. Graphene nanoribbons whose edge is an armchair edge obtained by irradiating sheet-like graphene with an ion beam formed by ionizing water molecules or water molecule-agglomerated clusters.
